(19) United States
(12) Patent Application Publication
(10) Pub. No.: US 2009/0237168 A1
(43) Pub. Date: Sep. 24, 2009

(54) VOLTAGE-CONTROLLED OSCILLATOR

(76) Inventor: David Wilson, Scotland (GB)

Correspondence Address: REED SMITH LLP, P.O. BOX 488, PITTSBURGH, PA, 15230-0488, US

(21) Appl. No.: 12/441,896

(22) PCT Filed: Sep. 10, 2007
(86) PCT No.: PCT/GB07/03397

§ 371 Date: Mar. 18, 2009

(30) Foreign Application Priority Data
Sep. 21, 2006 (GB) 0618675.3

(51) Int. Cl. H03B 1/00; H03B 27/00

(52) U.S. Cl. 331/50

(57) ABSTRACT

A voltage controlled oscillator comprises first and second voltage controlled oscillator cones (4, 6) for generating I and Q quadrature components respectively. Each of the voltage controlled oscillator cores comprises an inductor (41, 61). A connecting member (70) is electrically coupled to each of said inductors, thereby forcing the same common mode level in the I and Q core of the VCO. The invention has the advantage of providing a simple method of ensuring that the same common mode level is used in the I and Q cores of a cross-coupled VCO, and is particularly advantageous at high operating frequencies. The invention also has the advantage of overcoming potential start up issues, and reduces the sensitivity to device mismatch effects which become more apparent when designing in small geometry processes such as 130 nm CMOS, as the smaller device sizes can often result in greater mismatches.

### FIELD OF THE INVENTION

This invention relates to a voltage controlled oscillator and a method of operating a voltage controlled oscillator, and in particular to a voltage controlled oscillator and method of forcing the same common-mode level in the I and Q core of a quadrature LC voltage controlled oscillator.

### BACKGROUND OF THE INVENTION

Many communication systems require a quadrature clock signal in order to achieve image rejection when mixing. A quadrature clock signal is typically generated using two identical voltage controlled oscillators (VCOs) as shown in FIG. 1, and as described in greater detail further below. The quadrature clock must have an accurate 90-degree phase shift, otherwise any error in this phase relationship will contribute to errors in the output data.

One known method of locking two identical voltage controlled oscillators into a 90 degrees phase shift (i.e. to achieve quadrature) is the “cross coupling” technique, as documented by A. Rofougaran et al in “A 900 MHz CMOS LC-oscillator with quadrature outputs” in IEEE Int. Solid State Circuits Conf. (ISSCC) Dig. Tech. Papers, pp. 392-393, 1996.

This idea is further developed by Chao-Shiun Wang et al in “A Low Phase Noise Wide Tuning Range CMOS Quadrature VCO using Cascade Topology” in Proceedings of 2004 IEEE Asia-Pacific Conference on Advanced System Integrated Circuits 2004, 4-5 Aug. 2004 Page(s):138-141. The VCO core described in this paper is used as the basis of the VCO in the present invention, although it will be appreciated that the invention may also be used with other types of VCO.

FIG. 2 is a diagram of the connectivity of first and second VCO cores 4, 6 according to the Chao-Shiun Wang reference mentioned above. The connectivity of each VCO core 4, 6 will not be discussed in great detail herein. Such detail may be found in the original Chao-Shiun Wang reference mentioned above, which is Incorporated herein by reference in its entirety.

The first VCO 4 provided for producing the I signal contains an inductor 41 and a variable capacitor 42 connected as shown. It is noted that the variable capacitor is voltage controlled, for example using an analogue voltage or digital selection. The second VCO 6 provided for producing the Q signal is identical to the first VCO 4, save for different inputs and outputs, and also has an inductor 61 and a variable capacitor 62. As above, the variable capacitor is voltage controlled, for example using an analogue voltage or digital selection.

The cross coupling into the cascade devices of the VCO cores 4, 6 (see FIGS. 1 and 2) forces the first and second VCO cores 4, 6 to operate with a 90 degrees phase difference. The common mode level in each VCO core is determined by the switching devices and the current in the core (controlled by an automatic gain control loop and affected by the matching of the bias devices). In ideal simulation conditions, the matching is perfect and the I and Q cores operate at the same common mode level. However, once realistic mismatch properties are introduced, the common mode levels diverge, which has the effect of causing a phase error.

The dependence of I and Q matching on the common mode level is not always observed as quadrature VCOs are sometimes designed using two separate inductors in each core, with one end of both inductors connected to either the positive supply rail or to ground. In the case of the Wang circuit, the use of this configuration is not possible. This is because the Wang circuit requires switching devices both above and below the LC-tank. Using two separate core inductors with a ground or supply connection would result in the common mode level being forced to this voltage and prevent correct operation of the switching devices. In view of this limitation, the sensitivity to common mode level becomes more of an issue in the Wang circuit.

Alternative solutions are available. For example, the impact of device mismatch can be reduced by improving the matching in the bias circuit and the switching devices. However, this is achieved by increasing the device sizes. This in turn has the disadvantage of increasing the chip area and, more importantly, increases the parasitic capacitive loading in the VCO core. This is critical in high-speed communication systems such as ultra-wideband as it limits the maximum oscillating frequency of the VCO and, in turn, the maximum operating frequency of the transceiver. Therefore, such solutions are not possible in a VCO intended for use in a ultra-wideband system, where operating frequencies of 8.5 GHz and higher are required.

Common mode feedback may also be used to correct differences in the common mode levels. However, the active circuitry required for this type of solution consumes power, area and design effort. Common mode feedback also has the disadvantage of producing an additional noise source, which is problematic in systems such as ultra-wideband which have very tight phase noise requirements.

It is therefore an aim of the present invention to provide a voltage controlled oscillator and method of operating a voltage controlled oscillator, in which the above mentioned disadvantages are avoided.

### SUMMARY OF THE INVENTION

According to a first aspect of the present invention, there is provided a voltage controlled oscillator comprising first and second voltage controlled oscillator cores for generating I and Q quadrature components respectively. Each of the voltage controlled oscillator cores comprises an inductor. A connecting member is electrically coupled to each of said inductors.

According to a second aspect of the present invention, there is provided a method of forcing a common mode level in a voltage controlled oscillator, the voltage controlled oscillator comprising first and second voltage controlled oscillator cores for generating I and Q quadrature components respectively, each core comprising an inductor. The method comprises the step of electrically coupling said inductors together using a connecting member.

The invention has the advantage of providing a simple method of ensuring that the same common mode level is used in the I and Q cores of a cross-coupled VCO, and reduces the sensitivity of the VCO to device mismatch effects. This improved robustness is crucial for communication systems which rely on an accurate phase difference between the I and Q channels. These issues become more apparent when designing in small geometry processes such as 130 nm CMOS, since the smaller device sizes can often result in greater mismatches.

According to another aspect of the present invention, there is provided a method of assisting start-up in a voltage controlled oscillator, the voltage controlled oscillator comprising first and second voltage controlled oscillator cores for generating I and Q quadrature components respectively, each core comprising an inductor. The method comprises the step of electrically coupling said inductors together using a connecting member, thereby assisting start-up of the voltage controlled oscillator.

Thus, the invention also has the advantage of overcoming potential start up issues (as discussed in greater detail below).

### BRIEF DESCRIPTION OF THE DRAWINGS

For a better understanding of the present invention, and to show more clearly how it may be carried into effect, reference will now be made, by way of example only, to the following drawings in which:

FIG. 1 is a block schematic diagram of a VCO for producing quadrature outputs;

FIG. 2 is a circuit diagram of the two VCO cores used in the VCO of FIG. 1;

FIG. 3 is a circuit diagram of the two VCO cores having a connecting member according to the present invention;

FIG. 4 is a representation of a physical implementation of the connecting member according to the present invention; and

FIGS. 5a and 5b are schematic diagrams illustrating alternative examples of how the connecting member and inductors may be connected.

### DETAILED DESCRIPTION OF THE PREFERRED EMBODIMENTS

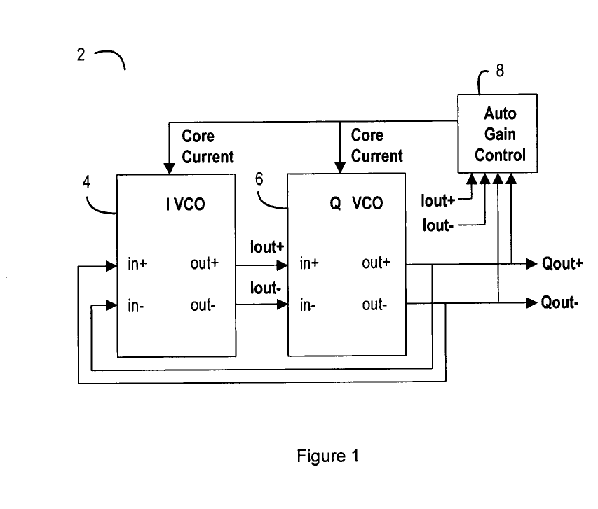

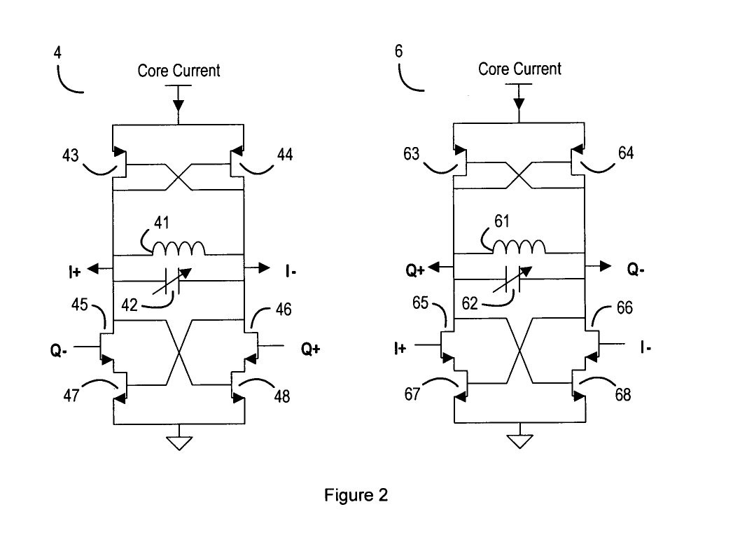

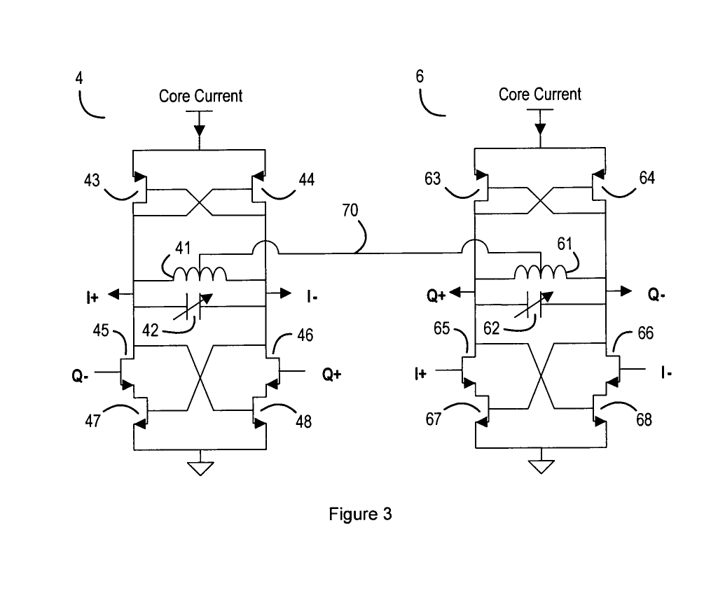

FIG. 1 is a block schematic diagram showing the structure and connectivity of a quadrature VCO 2. The quadrature VCO 2 comprises first and second VCO cores 4, 6 for producing I and Q quadrature outputs, respectively. The first and second VCO cores 4, 6 themselves are described in more detail in FIGS. 2 and 3 below.

An auto gain control block 8 provides current to both the first and second VCO cores 4, 6. The “I” VCO core 4 produces Iout+ and Iout− output signals. These output signals are provided as inputs to the second VCO core 6 (the “Q” core), with Iout+ being provided to the positive input terminal “in+” of the second VCO core 6, and Iout− being provided to the negative input terminal “in−” of the second VCO core 6 (i.e. the Q core). The Q VCO core 6 then produces Qout+ and Qout− output signals.

The Qout+ and Qout− output signals are further provided as inputs to the first VCO core 4 (i.e. the I VCO) for producing Iout+ and Iout− signals, thus forming a feedback path. However, the Q VCO outputs are inverted when they are fed back to the I VCO core 4, in that the Qout+ is provided to the in− input of the I VCO core 4, and Qout− is provided to the in+ input of the I VCO core 4.

All four outputs (Qout+, Qout−, Iout+, Iout−) are input to auto gain control block 8, which adjusts the current supplied to the two cores 4, 6 accordingly. The auto gain control block 8 forms part of an amplitude control loop which is used to regulate optimum signal swing.

The four outputs (Iout+, Iout−, Qout+, Qout−) are also output from the VCO 2 as the I and Q quadrature outputs respectively.

FIG. 2 is a circuit diagram of the VCO cores 4, 6 according to the Chao-Shiun Wang reference mentioned above.

The connectivity of each VCO core 4, 6 will not be discussed in great detail herein. Such detail may be found in the original Chao-Shiun Wang reference mentioned above, which is incorporated herein by reference in its entirety.

The I VCO 4 contains an inductor 41 and a variable capacitor 42 connected as shown. The Q VCO 6 is identical to the I VCO 4, except that the inputs and outputs are inverted. In other words, where the I VCO 4 has Qout− and Qout+ as inputs and I out− and Iout+ as outputs, the Q VCO 6 has Iout− and Iout+ as inputs and Qout− and Qout+ as outputs. The Q VCO 6 has an inductor 61 and a variable capacitor 62.

The I VCO 4 further comprises six coupling devices 43, 44, 45, 46, 47 and 48, where coupling devices 43 and 44 and 47 and 48 form a cross-coupled pair. This cross-coupled pair acts like a negative resistance.

The Q VCO 6 further comprises six coupling devices 63, 64, 65, 66, 67 and 68, where coupling devices 63 and 64 and 67 and 68 form a cross-coupled pair.

The cross coupling into the cascade devices of the VCO cores 4, 6 (see FIGS. 1 and 2) forces the VCOs to operate with 90 degrees phase difference.

As described above, the common mode level in each VCO core is determined by the switching devices and the current in the core as controlled by the automatic gain control block 8 and affected by the matching of the bias devices. In ideal simulation conditions, the matching is perfect and the I and Q cores operate at the same common mode level. However, once realistic mismatch properties are introduced, the common mode levels diverge and the effect is seen as a phase error.

According to the present invention, the solution is to make use of the “virtual ground” point present at the centre point of each inductor 41, 61. This centre point should see no DC current and can be used to connect the DC levels within the core.

An exemplary embodiment of the invention is shown in FIG. 3. In this Figure, a pair of VCO cores 4, 6 are provided that correspond to those shown in FIG. 2. In accordance with the invention, a connecting member 70 is provided to connect the inductors 41, 61 together. Preferably, connecting member 70 takes the form of a metal track. The wide, thick metal track offers very low resistance for the connection.

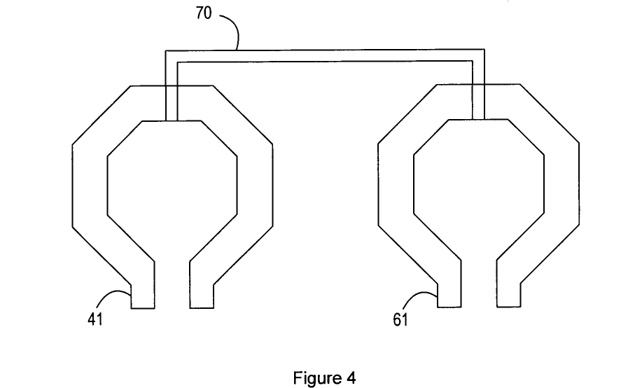

FIG. 4 is a representation of a physical implementation of the inductor structure and centre tap connecting member according to the present invention.

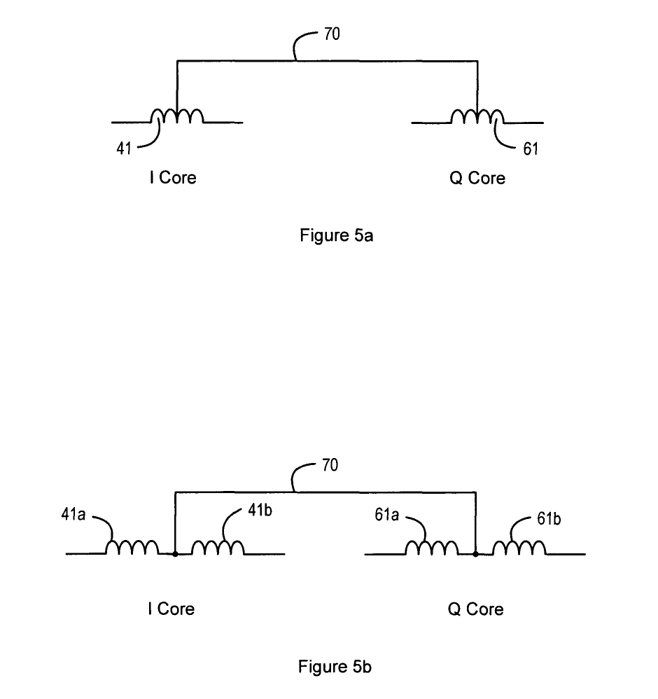

Preferably, the inductors 41, 61 are symmetrical inductors as illustrated in the schematic diagram of FIG. 5a, and the connecting member 70 arranged to connect the centres or mid-points of the inductors 41, 61 together.

Alternatively, each inductor 41, 61 may comprise two separate inductor elements 41a and 41b, and 61a and 61b as shown in FIG. 5b. In such an arrangement the connecting member 70 is connected to a node connecting the first and second inductor elements 41a and 41b, and 61a and 61b, respectively. It will also be appreciated that an embodiment comprising a mixture of FIGS. 5a and 5b would also be feasible, in which one of the inductors 41, 61 comprises a symmetrical inductor, while the other inductor 41, 61 comprises first and second inductor elements 41a/41b or 61a/61b.

Simulation of the various circuit arrangements indicate that the connecting member 70 results in a significant reduction in sensitivity to device mismatch. As mentioned above, benefits are also observed during startup, when a shared common mode helps reduce the likelihood of unwanted startup states, for example, in which one VCO has a high common mode and the other VCO has a low common mode. This state can lengthen settling time at startup as a low common mode in, for example, the I VCO 4 will provide very low overdrive to the cascade devices of the Q VCO 6. This would make it more difficult for the high common mode level of the Q VCO 6 to be reduced and it in turn will provide high overdrive to the I VCO cascade devices, keeping the I VCO 4 common mode level low.

Although the invention is shown with regard to a quadrature VCO, the method of improving I & Q matching by correcting differences in common mode levels could also be applied to other circuits, for example other LC VCOs, quadrature dividers or quadrature buffering.

The invention has the advantage of providing a simple method of ensuring that the same common mode level is used in the I and Q cores of a cross-coupled VCO. The invention is particularly advantageous at high frequencies, such as those used in ultra-wideband systems, when alternative methods of common mode correction can have the undesired effect of reducing the operating frequency.

It should be noted that the above-mentioned embodiments illustrate rather than limit the invention, and that those skilled in the art will be able to design many alternative embodiments without departing from the scope of the appended claims. The word “comprising” does not exclude the presence of elements or steps other than those listed in a claim, “a” or “an” does not exclude a plurality, and a single processor or other unit may fulfil the functions of several units recited in the claims. Any reference signs in the claims shall not be construed so as to limit their scope.

1. A voltage controlled oscillator, comprising:
first and second voltage controlled oscillator cores for generating I and Q quadrature components respectively, each of the voltage controlled oscillator cores comprising an inductor; and
a connecting member electrically coupled to each of said inductors.

2. The voltage controlled oscillator as claimed in claim 1, wherein at least one of the inductors is a symmetrical inductor, and the connecting member is coupled to a mid-point of said at least one inductor.

3. The voltage controlled oscillator as claimed in claim 1, wherein at least one of the inductors comprises first and second inductor elements, and the connecting member is connected to a node connecting the first and second inductor elements.

4. The voltage controlled oscillator as claimed in claim 1, wherein the connecting member has a low electrical resistance.

5. The voltage controlled oscillator as claimed in claim 1, wherein the connecting member comprises a metal track.

6. The voltage controlled oscillator as claimed in claim 1, wherein the voltage controlled oscillator is a LC voltage controlled oscillator.

7. An ultra-wideband device comprising a voltage controlled oscillator, said voltage controlled oscillator comprising:
first and second voltage controlled oscillator cores for generating I and Q quadrature components respectively, each of the voltage controlled oscillator cores comprising an inductor, and
a connecting member electrically coupled to each of said inductors.

8. A method of forcing a common mode level in a voltage controlled oscillator, the voltage controlled oscillator comprising first and second voltage controlled oscillator cores for generating I and Q quadrature components respectively, each core comprising an inductor; the method comprising:
electrically coupling said inductors together using a connecting member.

9. The method as claimed in claim 8, wherein electrically coupling said inductors comprises electrically coupling at least one symmetrical inductor, and further comprising the step of connecting the connecting member to a mid-point of said at least one symmetrical inductor.

10. The method as claimed in claim 8, wherein electrically coupling said inductors comprises electrically coupling first and second inductor elements of at least one of said inductors, and further comprising the step of connecting the connecting member to a node connecting the first and second inductor elements.

11. The method as claimed in claim 8, wherein electrically coupling said inductors comprises electrically coupling said inductors together using a low electrical resistance connecting member.

12. The method as claimed in claim 11, wherein the connecting member comprises a metal track.

13. The method as claimed in claim 8, wherein the voltage controlled oscillator is a LC voltage controlled oscillator.

14. A method of assisting start-up in a voltage controlled oscillator, the voltage controlled oscillator comprising first and second voltage controlled oscillator cores for generating I and Q quadrature components respectively, each core comprising an inductor; the method comprising:
electrically coupling said inductors together using a connecting member, thereby assisting start-up of the voltage controlled oscillator.
